(19) United States
(12) Patent Application Publication
(10) Pub. No.: US 2010/0187650 A1
(43) Pub. Date: Jul. 29, 2010

(54) INSULATED WELL WITH A LOW STRAY CAPACITANCE FOR ELECTRONIC COMPONENTS

(75) Inventors: Patrick Poveda, Villedomer (FR); Benjamin Morillon, Tours (FR); Erwan Bruno, Ballan-Mire (FR)

Correspondence Address: STMicroelectronics Inc.;c/o WOLF, GREENFIELD & SACKS, P.C., 600 Atlantic Avenue, BOSTON, MA, 02210-2206, US

(73) Assignee: STMicroelectronics (Tours) SAS, Tours (FR)

(21) Appl. No.: 12/690,717

(22) Filed: Jan. 20, 2010

(30) Foreign Application Priority Data
Jan. 23, 2009 (FR) 09/50420

(51) Int. Cl. H01L 29/06; H01L 21/762

(52) U.S. Cl. 257/506; 438/433; 257/E29.018; 257/E21.546

(57) ABSTRACT

A structure including at least one electronic component formed in a semiconductor stack comprising a heavily-doped buried silicon layer of a first conductivity type extending on a lightly-doped silicon substrate of a second conductivity type and a vertical insulating trench surrounding the component. The trench penetrates, into the silicon substrate, under the silicon layer, down to a depth greater than the thickness of the space charge region in the silicon substrate.

### CROSS REFERENCE TO RELATED APPLICATIONS

This application claims the priority benefit of French patent application Ser. No. 09/50420, filed on Jan. 23, 2009, entitled “INSULATED WELL WITH A LOW STRAY CAPACITANCE FOR ELECTRONIC COMPONENTS,” which is hereby incorporated by reference to the maximum extent allowable by law.

### BACKGROUND OF THE INVENTION

1. Field of the Invention

The present invention relates to electronic components formed in and on a semiconductor structure and insulated from one another. More specifically, the present invention relates to a structure in which stray capacitances between components and between each component and the substrate are decreased. The present invention also relates to a method for manufacturing such a structure.

2. Discussion of the Related Art

Conventionally, electronic components formed in and on a semiconductor substrate, for example, power components, are insulated at the surface of the stacking by PN junctions. If the substrate is of type N, P regions laterally insulate the electronic components from one another. This type of insulation has the disadvantage of taking up a significant surface area to be efficient. Indeed, the width of the P region is at least equal to twice its depth. It is further generally considered that a PN-junction insulation is not optimal as far as the stray capacitances between component and substrate are concerned.

Thus, to limit the surface area taken up and to decrease stray capacitances, it has been provided to form electronic components in and on substrates of silicon on insulator type (SOI) and to insulate the components from one another by means of dielectric materials.

FIG. 1 illustrates one of such structures provided by the applicant in the patent application filed under number FR 2914497. Two diodes D1 and D2 are formed side by side in an SOI-type structure which comprises an N-type doped semiconductor layer formed on a semiconductor substrate 1 with an interposed insulating layer 3. Diodes D1 and D2 are laterally insulated by insulating regions 5, for example, made of silicon oxide, which cross the semiconductor layer and join insulating layer 3. Each diode is thus formed by an N-type doped semiconductor well 7 at the surface of which a P-type doped region 9 is formed. Each well 7 is surrounded (bottom, lateral walls, and a portion of its upper surface) by a heavily-doped N-type region 11 (N⁺). An anode contact 13 and a cathode contact 15 are respectively formed on regions 9 and 11 of diode D1 and an anode contact 17 and a cathode contact 19 are formed, respectively, on regions 9 and 11 of diode D2. Layer 3 and insulating regions 5 for example have thicknesses greater than 2 μm and enable for the stray capacitances between components and between each component and the substrate to be very small.

FIG. 2 is an electric diagram illustrating an example of a device for protecting a data transmit line 21 (I/O) against overvoltages. The device of FIG. 2 comprises two low-capacitance diodes D1 and D2 and a protection diode DP. Diode D2 has its cathode 19 connected to line 21 and its anode 17 connected to ground. When a negative overvoltage appears on line 21, diode D2 is forward biased and turns on. Diode D1 and protection diode DP are arranged, in series, in parallel with diode D2. Diode D1 has its anode 13 connected to line 21 and its cathode 15 connected to the cathode of protection diode DP. The anode of protection diode DP is grounded. When a positive overvoltage greater than the avalanche voltage of protection diode DP appears on line 21, protection diode DP avalanches and conducts the current, diode D1 being also forward biased.

It is generally desired for circuits of protection against overvoltages such as that of FIG. 2 to affect as little as possible the signals flowing through the line. To achieve this, the stray capacitances linked to the protection circuit must be as low as possible. Thus, protection diodes D1 and D2 may correspond to the diodes of FIG. 1 and protection diode DP may also be formed in a similar well.

However, SOI-type structures have various disadvantages. SOI-type wafers are relatively expensive as compared with solid wafers if specific characteristics are imposed to each of the wafer elements. Further, for a good vertical insulation, trenches comprising a thick buried oxide layer are generally used, which may cause a significant deformation, making the wafer processing difficult in manufacturing operations.

There thus is a need for a structure enabling to insulate electronic components, which is relatively inexpensive, of low bulk, and which limits stray capacitances between components and between each component and the substrate.

### SUMMARY OF THE INVENTION

An object of an embodiment of the present invention is to provide a low-cost and low-bulk structure comprising electronic components insulated from one another.

Another object of an embodiment of the present invention is to provide a structure in which stray capacitances between components and between each component and the substrate are very low.

Another object of an embodiment of the present invention is to provide a method for manufacturing such a structure.

Thus, an embodiment of the present invention provides a structure comprising at least one electronic component formed in a semiconductor stack comprising a heavily-doped buried silicon layer of a first conductivity type extending over a lightly-doped silicon substrate of a second conductivity type and a vertical insulating trench surrounding the component, the trench penetrating, into the silicon substrate, under the silicon layer, down to a depth greater than the thickness of the space charge region in the silicon substrate.

According to an embodiment of the present invention, the silicon substrate is doped with a dopant concentration smaller than 8.5×10 atoms/cm³ and the buried silicon layer is doped to a dopant concentration greater than 10¹⁹ atoms/cm³.

According to an embodiment of the present invention, the space charge region in the silicon substrate has a thickness comprised between 1 μm and 3.3 μm.

According to an embodiment of the present invention, the structure further comprises heavily-doped regions of the first conductivity type formed along the trench, above the heavily-doped layer of the first conductivity type.

According to an embodiment of the present invention, the insulating trench has insulated walls and is filled with polysilicon.

According to an embodiment of the present invention, the electronic component is a diode formed in an upper silicon layer of the first conductivity type extending on the heavily-doped silicon layer of the first conductivity type.

According to an embodiment of the present invention, the first conductivity type is type N.

An embodiment of the present invention further provides a method for manufacturing a semiconductor structure intended to contain an electronic component, comprising the successive steps of:

forming an upper silicon layer extending on a lightly-doped silicon substrate of a second conductivity type with an interposed heavily-doped buried silicon layer of the first conductivity type;

forming a trench, along the contour of the component, in the upper silicon layer;

performing a doping of the first conductivity type of the walls of the upper silicon layer, from the trench;

continuing the trench in the silicon substrate down to a depth greater than the thickness of the space charge region in the silicon substrate; and

forming, on the walls and the bottom of the trench, an insulating layer.

According to an embodiment of the present invention, the method further comprises a step of filling of the trench with polysilicon.

According to an embodiment of the present invention, the buried heavily-doped silicon layer of the first conductivity type is formed by implantation/diffusion of dopants at the surface of the silicon substrate and the upper silicon layer is formed by epitaxy on the buried silicon layer.

The foregoing objects, features, and advantages of the present invention will be discussed in detail in the following non-limiting description of specific embodiments in connection with the accompanying drawings.

### BRIEF DESCRIPTION OF THE DRAWINGS

FIG. 1, previously described, illustrates a known structure comprising electronic components insulated from one another;

FIG. 2, previously described, illustrates an example of a known circuit for protecting a data transmission line against overvoltages;

FIG. 3 illustrates a structure comprising electronic components insulated from one another according to an embodiment of the present invention; and

FIGS. 4A to 4G illustrate results of steps of a method for manufacturing the structure of FIG. 3 according to an embodiment of the present invention.

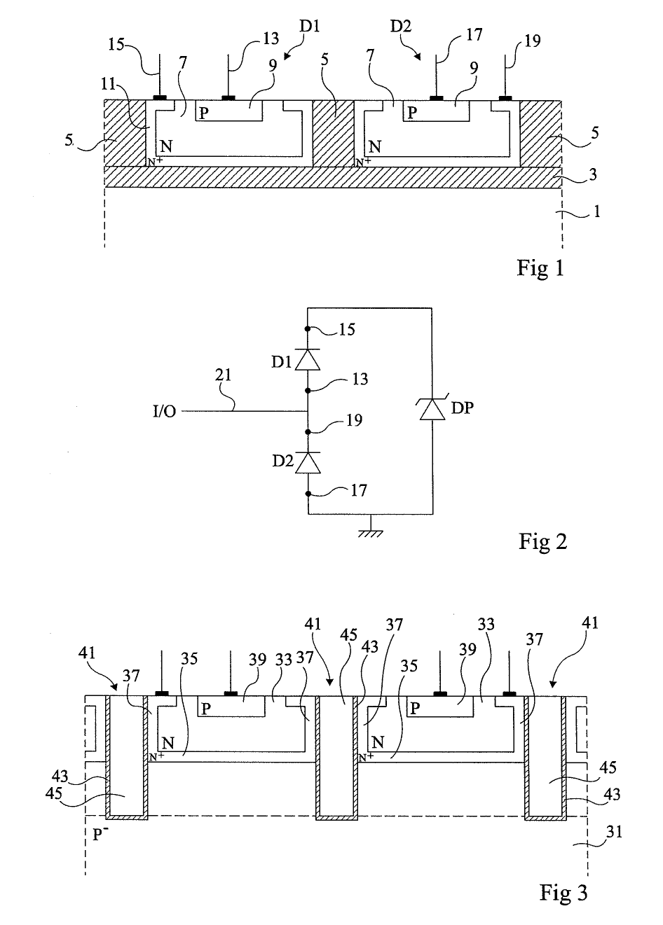

### DETAILED DESCRIPTION

For clarity, the same elements have been designated with the same reference numerals in the different drawings and, further, as usual in the representation of integrated circuits, the various drawings are not to scale.

FIG. 3 illustrates a structure comprising electronic components insulated from one another according to an embodiment of the present invention.

Two N-type doped silicon wells 33 are formed on a lightly-doped P-type silicon substrate 31 (P⁻). In FIG. 3, the shown electronic components are diodes, D1 and D2, but it should be understood that any electronic component may be formed in wells 33. A heavily-doped N-type layer 35 (N⁺) is formed at the interface between wells 33 and substrate 31. Heavily-doped N-type regions 37 extend on the lateral walls of wells 33 and on part of their upper surfaces. P-type doped anode regions 39 of diodes D1 and D2 are formed at the surface of wells 33. Wells 33 are laterally insulated by insulating trenches 41 which penetrate into substrate 31. In the shown example, the walls and the bottom of trenches 41 are covered with an insulating layer 43, for example, made of silicon oxide, and the space remaining in trenches 41 is filled with polysilicon 45 or any other material enabling to fill this space. As a numerical example, wells 33 may have a thickness of approximately 10 μm and heavily-doped N-type layer 35 has a thickness of approximately 5 μm.

The association of lightly-doped P-type substrate 31 and of heavily-doped N-type layer 35 forms a space charge region which extends deeply into substrate 31, due to the doping difference between these regions. The limit of this space charge region is shown in dotted lines in FIG. 3. The dopings of layer 35 and of substrate 31 are provided so that the space charge region in substrate 31 has a thickness greater than approximately 3 μm. For example, these dopings are relatively greater than 10¹⁹ atoms/cm³ for layer 35 and smaller than 8.5×10¹³ atoms/cm³ for substrate 31, for example comprised between 8×10¹² atoms/cm³ and 8.5×10¹³ atoms/cm³. A space charge region having a 8-μm thickness amounts, in terms of stray capacitance, to a silicon oxide layer having a thickness of approximately 2.5 μm. Indeed, the permittivity of intrinsic silicon is approximately equal to 3 times the permittivity of silicon oxide. Thus, the vertical insulation between component and substrate, formed by the structure of FIG. 3, is equivalent to that of known structures on SOI substrates, without using such substrates. The man skilled in the art will easily determine the dopings of layer 35 and substrate 31 to obtain a space charge region having a thickness comprised between 3 μm and 10 μm, such a thickness corresponding to a buried oxide having a thickness comprised between 1 μm and 3.3 μm.

Trenches 41 penetrate into substrate 31 down to a depth greater than the thickness of the space charge region in substrate 31. This enables limiting stray capacitances between two neighboring components formed in neighboring wells 33. Indeed, if insulating trenches 41 stop at the interface between layer 35 and substrate 31, this may create high stray capacitances may form between two neighboring components, under insulating trenches 41. The insulation between wells is then ineffective. The structure of FIG. 3 enables to avoid this, due to insulating trenches 41 forming an obstacle to the creation of such stray capacitances.

A structure laterally insulated by an insulating trench 41 is thus obtained. This insulation has, in known fashion, the advantage of ensuring low stray capacitances between components and to have a decreased bulk (smaller than that of junction insulations). Further, wells 33 are insulated from substrate 31 by a junction which, contrary to common belief, provides effects identical to those of a buried oxide layer having a thickness of a few micrometers. Stray capacitances between each component and the substrate are thus decreased without requiring the use of an expensive SOI structure likely to be deformed.

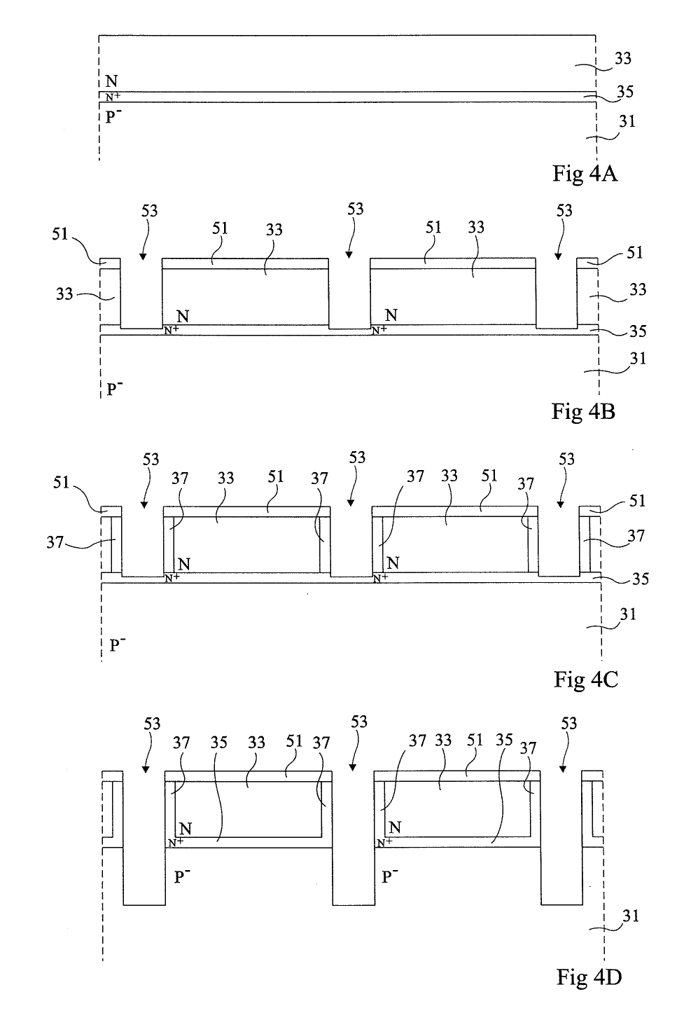

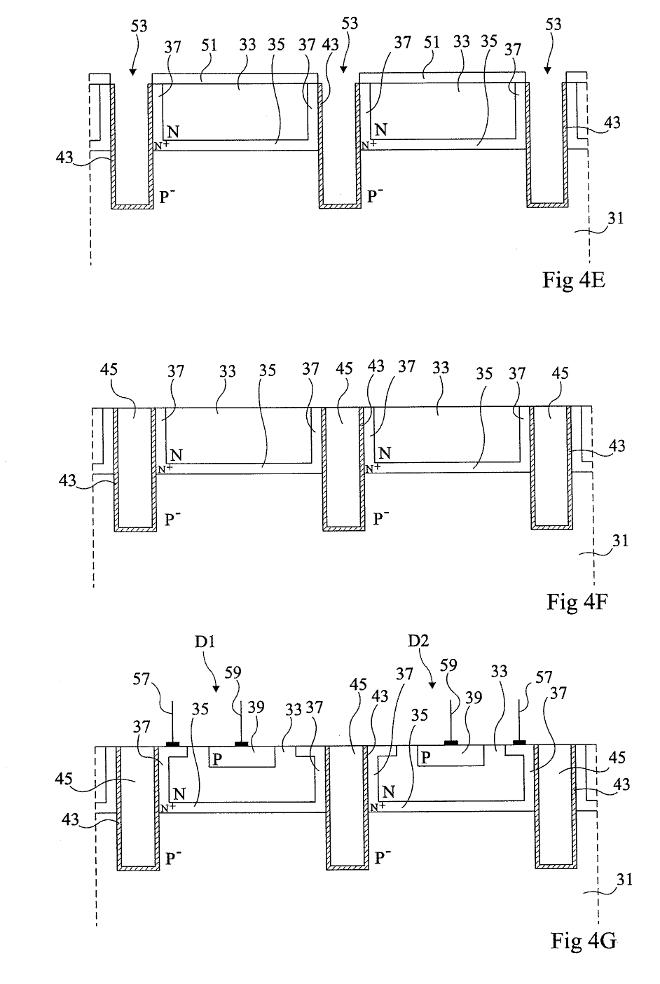

FIGS. 4A to 4G illustrate results of steps of a method according to an embodiment of the present invention providing the structure of FIG. 3.

FIG. 4A shows a lightly-doped P-type silicon substrate 31 (P⁻) on which is formed a heavily-doped N-type silicon layer 35 (N⁺). Layer 35 may be formed, for example, by arsenic or antimony implantation, and have a thickness of approximately 5 μm after diffusion. A thick N-type doped silicon layer 33 is formed by epitaxy on layer 35. As an example, substrate 31 may be doped with a dopant concentration smaller than 1.5×10¹³ atoms/cm³ and layer 35 may be doped with a dopant concentration on the order of 10¹⁹ atoms/cm³. Layer 33 may be doped with a dopant concentration on the order of 2×10¹³ atoms/cm³ and have a thickness of approximately 10 μm.

At the step illustrated in FIG. 4B, a mask 51 comprising openings through which trenches 53 are formed in the upper silicon layer, to form silicon wells 33, has been formed at the surface of silicon layer 33. Mask 51 may for example be made of silicon oxide or of silicon nitride. Trenches 53, for example resulting from a plasma etch, stop in heavily-doped silicon layer 35. Indeed, since silicon layer 35 has a thickness of a few micrometers, it enables to stop the etching, to avoid for the in-depth dispersion of the etching to become critical. As a numerical example, trenches 53 may have a thickness ranging between 1 and 2 μm.

At the step illustrated in FIG. 4C, a pre-deposition 37 of POCl₃ has been formed on the walls of trenches 53, to enable, in a subsequent anneal step, the forming of regions heavily doped with phosphorus (N type) on the walls of wells 33. A deoxidation may then be carried out to eliminate the oxide formed at the surface of the walls of trenches 53.

At the steps illustrated in FIG. 4D, a new plasma etch is carried out to increase the depth of trenches 53 so that they cross heavily-doped N-type silicon layer 35 and penetrate into lightly-doped P-type substrate 31. This step is carried out by means of mask 51. An anneal enabling POCl₃ to diffuse into silicon wells 33 is then performed, to form heavily-doped N-type regions 37 on the upper part of the walls of trenches 53, in wells 33. It should be noted that the anneal may be performed before the step of FIG. 4D when deep trenches 53 are formed. As an example, trenches 53 may penetrate into silicon substrate 31 down to a depth ranging between approximately 10 μm and approximately 15 μm, as described hereabove.

At the step illustrated in FIG. 4E, a thin insulating layer 43 has been formed on the walls and the bottom of trenches 53, for example, by thermal oxidation, to form a silicon oxide layer 43.

At the step illustrated in FIG. 4F, trenches 53 have been filled with polysilicon or with any other material 45 well adapted to filling trenches 53, for example, an oxide. Mask 51 is then removed.

At the step illustrated in FIG. 4G, electronic components have been formed in wells 33, in the shown example, of diodes D1 and D2 identical to that of FIG. 3, which comprise P-type doped regions 39 formed at the surface of each of wells 33. Regions 39 form the anodes of diodes D1 and D2. In the shown example, contacts 57 and 59 are taken, respectively, on cathode region 37 and anode region 39 of diodes D1 and D2. Heavily-doped N-type regions may be formed at the surface of wells 33, at the level of regions 37, to help the forming of the cathode contacts 59.

Specific embodiments of the present invention have been described. Various alterations and modifications will occur to those skilled in the art. In particular, it should be noted that the components described herein are examples only and that other components may be formed in insulated wells 33, for example, protection diodes or other electronic components, for example, high-frequency power components.

It should also be noted that structures similar to those disclosed herein may be devised by inverting all conductivity types and doping types.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

What is claimed is:

1. A structure comprising at least one electronic component formed in a semiconductor stack comprising a heavily-doped buried silicon layer of a first conductivity type extending on a lightly-doped silicon substrate of a second conductivity type and a vertical insulating trench surrounding the component, wherein the trench penetrates, into the silicon substrate, under the silicon layer, down to a depth greater than the thickness of the space charge region in the silicon substrate.

2. The structure of claim 1, wherein the silicon substrate is doped with a dopant concentration smaller than 8.5×10¹³ atoms/cm³ and the buried silicon layer is doped to a dopant concentration greater than 10¹⁹ atoms/cm³.

3. The structure of claim 1, wherein said space charge region in the silicon substrate has a thickness comprised between 1 μm and 3.3 μm.

4. The structure of claim 1, further comprising heavily-doped regions of the first conductivity type formed along the trench, above the heavily-doped layer of the first conductivity type.

5. The structure of claim 1, wherein the insulating trench has insulated walls and is filled with polysilicon.

6. The structure of claim 1, wherein the electronic component is a diode formed in an upper silicon layer of the first conductivity type extending on the heavily-doped silicon layer of the first conductivity type.

7. The structure of claim 1, wherein the first conductivity type is type N.

8. A method for manufacturing a semiconductor structure intended to contain an electronic component, comprising the successive steps of:
forming an upper silicon layer extending on a lightly-doped silicon substrate of a second conductivity type with an interposed heavily-doped buried silicon layer of the first conductivity type;
forming a trench, along the contour of the component, in the upper silicon layer;
performing a doping of the first conductivity type of the walls of the upper silicon layer, from the trench;
continuing the trench in the silicon substrate down to a depth greater than the thickness of the space charge region in the silicon substrate; and
forming, on the walls and the bottom of the trench, an insulating layer.

9. The method of claim 8, further comprising a step of filling of the trench with polysilicon.

10. The method of claim 8, wherein the heavily-doped buried silicon layer of the first conductivity type is formed by implantation/diffusion of dopants at the surface of the silicon substrate and wherein the upper silicon layer is formed by epitaxy on the buried silicon layer.
